(19) United States
(12) Patent Application Publication
(10) Pub. No.: US 2021/0296176 A1
(43) Pub. Date: Sep. 23, 2021

(54) STRUCTURE AND METHOD FOR ELECTRONIC DIE SINGULATION USING ALIGNMENT STRUCTURES AND MULTI-STEP SINGULATION

(71) Applicant: SEMICONDUCTOR COMPONENTS INDUSTRIES, LLC, Phoenix, AZ (US)

(72) Inventors: Srinivasa Reddy YEDURU, Fishkill, NY (US); George CHANG, Tempe, AZ (US); Gordon M. GRIVNA, Mesa, AZ (US)

(73) Assignee: SEMICONDUCTOR COMPONENTS INDUSTRIES, LLC, Phoenix, AZ (US)

(21) Appl. No.: 17/248,514

(22) Filed: Jan. 28, 2021

Related U.S. Application Data
(60) Provisional application No. 62/993,495, filed on Mar. 23, 2020.
(60) Provisional application No. 63/022,957, filed on May 11, 2020.

(51) Int. Cl. H01L 21/78; H01L 21/268; H01L 21/3065

(52) U.S. Cl. CPC H01L 21/78; H01L 21/3065; H01L 21/268

(57) ABSTRACT

A method for singulating a semiconductor wafer includes providing the semiconductor wafer having a plurality of semiconductor devices adjacent to a first surface, the plurality of semiconductor devices separated by spaces corresponding to where singulation lines will be formed. The method includes providing an alignment structure adjacent to the first surface and providing a material on a second surface of the semiconductor wafer, wherein the material is absent on the second surface directly below the alignment structure. The method includes passing an IR signal through the semiconductor wafer from the second surface to the first surface where the material is absent to detect the alignment structure and align a singulation device to the spaces where the singulation lines on will be formed. The method includes using the singulation device to remove portions of the layer of material aligned to the singulation lines and thereafter plasma etching the semiconductor wafer from the first surface to the second surface through the spaces to form the singulation lines thereby singulating the semiconductor wafer.

### CROSS-REFERENCE TO RELATED APPLICATIONS

This application claims priority from U.S. Provisional Application No. 62/993,495 filed on Mar. 23, 2020, and from U.S. Provisional Patent Application No. 63/022,957 filed on May 11, 2020, both of which are hereby incorporated by reference in their entirety.

### BACKGROUND

### Technical Field

The present disclosure relates, in general, to electronics and, more particularly, to semiconductor device structures and methods of forming semiconductor devices.

### Background

Prior semiconductor devices and methods for forming semiconductor devices are inadequate, for example resulting in excess cost, decreased reliability, relatively low performance, or dimensions that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 illustrates a top view of a semiconductor substrate in accordance with the present description;

FIG. 2 illustrates a bottom view of the semiconductor substrate of FIG. 1 in accordance with the present description;

FIG. 3 illustrates a top view of the semiconductor substrate of FIG. 1 in a see-through configuration to further illustrate the features of the top side and the bottom side in accordance with the present description;

FIGS. 4A, 4B, and 4C illustrate example alignment patterns in accordance with the present description

FIGS. 5, 6, 7, 8, 9, and 10 illustrates side views of the semiconductor substrate of FIGS. 1 and 2 at stages of fabrication in accordance with the present description;

FIG. 11 illustrates a top view of a semiconductor substrate accordance with the present description;

FIG. 12 illustrates a top view of a semiconductor substrate in accordance with the present description;

FIG. 13 illustrates a partial cross-sectional view of a semiconductor substrate at a step in fabrication in accordance with the present description;

FIGS. 14, 15, 16, 17, 18, 19, 20, and 21 illustrate partial cross-sectional views of the semiconductor substrate of FIG. 13 at various steps of fabrication in accordance with the present description; and

FIG. 22 illustrates partial top view of the semiconductor substrate during a step in fabrication in accordance with the present description.

The following discussion provides various examples of semiconductor devices and methods of manufacturing semiconductor devices. Such examples are non-limiting, and the scope of the appended claims should not be limited to the particular examples disclosed. In the following discussion, the terms “example” and “e.g.” are non-limiting.

For simplicity and clarity of the illustration, elements in the figures are not necessarily drawn to scale, and the same reference numbers in different figures denote the same elements.

Additionally, descriptions and details of well-known steps and elements are omitted for simplicity of the description.

For clarity of the drawings, certain regions of device structures, such as doped regions or dielectric regions, may be illustrated as having generally straight line edges and precise angular corners. However, those skilled in the art understand that, due to the diffusion and activation of dopants or formation of layers, the edges of such regions generally may not be straight lines and that the corners may not be precise angles.

Although the semiconductor devices are explained herein as certain N-type conductivity regions and certain P-type conductivity regions, a person of ordinary skill in the art understands that the conductivity types can be reversed and are also possible in accordance with the present description, taking into account any necessary polarity reversal of voltages, inversion of transistor type and/or current direction, etc.

In addition, the terminology used herein is for the purpose of describing particular examples only and is not intended to be limiting of the disclosure. As used herein, the singular forms are intended to include the plural forms as well, unless the context clearly indicates otherwise.

As used herein, “current-carrying electrode” means an element of a device that carries current through the device, such as a source or a drain of an MOS transistor, an emitter or a collector of a bipolar transistor, or a cathode or anode of a diode, and a “control electrode” means an element of the device that controls current through the device, such as a gate of a

MOS transistor or a base of a bipolar transistor.

The term “major surface” when used in conjunction with a semiconductor region, wafer, or substrate means the surface of the semiconductor region, wafer, or substrate that forms an interface with another material, such as a dielectric, an insulator, a conductor, or a polycrystalline semiconductor. The major surface can have a topography that changes in the x, y and z directions.

The terms “comprises”, “comprising”, “includes”, and/or “including”, when used in this description, are open ended terms that specify the presence of stated features, numbers, steps, operations, elements, and/or components, but do not preclude the presence or addition of one or more other features, numbers, steps, operations, elements, components, and/or groups thereof.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

Although the terms “first”, “second”, etc. may be used herein to describe various members, elements, regions, layers and/or sections, these members, elements, regions, layers and/or sections should not be limited by these terms. These terms are only used to distinguish one member, element, region, layer and/or section from another. Thus, for example, a first member, a first element, a first region, a first layer and/or a first section discussed below could be termed a second member, a second element, a second region, a second layer and/or a second section without departing from the teachings of the present disclosure.

It will be appreciated by one skilled in the art that words, “during”, “while”, and “when” as used herein related to circuit operation are not exact terms that mean an action takes place instantly upon an initiating action but that there may be some small but reasonable delay, such as propagation delay, between the reaction that is initiated by the initial action. Additionally, the term “while” means a certain action occurs at least within some portion of a duration of the initiating action.

The use of word “about”, “approximately”, or “substantially” means a value of an element is expected to be close to a state value or position. However, as is well known in the art there are always minor variances preventing values or positions from being exactly stated.

Unless specified otherwise, as used herein, the word “over” or “on” includes orientations, placements, or relations where the specified elements can be in direct or indirect physical contact.

Unless specified otherwise, as used herein, the word “overlapping” includes orientations, placements, or relations where the specified elements can at least partly or wholly coincide or align in the same or different planes.

It is further understood that the examples illustrated and described hereinafter suitably may have examples and/or may be practiced in the absence of any element that is not specifically disclosed herein.

### DETAILED DESCRIPTION OF THE DRAWINGS

Die singulation including plasma singulation or plasma etching of semiconductor wafers is a promising approach to separate individual semiconductor dies from the wafer. Although progress has been made, additional improvements and enhancements are desired to process larger diameter wafers (e.g., 300 millimeter or larger) as well as semiconductor wafers that have thick materials adjacent to the back side of the wafers. Such materials include, for example, back metal films, wafer back coating films, and/or die attach films.

In general, the present description and examples relate to semiconductor device structures and methods for singulating semiconductor wafers that are larger in diameter and/or semiconductor wafers that include thick back side materials.

In an example, a method of singulating semiconductor die from a semiconductor wafer includes providing the semiconductor wafer formed from a semiconductor material and having semiconductor dies formed adjacent to a first surface of the semiconductor wafer, the semiconductor dies separated from each other by singulation regions where singulation lines are to be formed, wherein the first surface includes an alignment structure. The method includes attaching the semiconductor wafer to a first carrier substrate, wherein the first surface of the semiconductor wafer is adjacent to the first carrier substrate. The method includes removing a portion of the semiconductor wafer from the second surface to provide a thinned surface opposite to the first surface. The method includes providing a material on the thinned surface of the semiconductor wafer except for an area corresponding to the location of the alignment structure on the first surface. The method includes removing portions of the material using the alignment structure so that the removed portions of the material correspond to the singulation regions on the first surface. The method includes thereafter plasma singulating the semiconductor wafer through the singulation regions from the first surface inward towards the thinned surface.

In an example, a method for singulating a semiconductor wafer includes providing the semiconductor wafer having a plurality of semiconductor devices adjacent to a first surface, the plurality of semiconductor devices separated by spaces corresponding to where singulation lines will be formed. The method includes providing an alignment structure adjacent to the first surface and providing a material on a second surface of the semiconductor wafer, wherein the material is absent on the second surface directly below the alignment structure. The method includes passing an IR signal through the semiconductor wafer from the second surface to the first surface where the material is absent to enable detection of the alignment structure and align a singulation device to the spaces where the singulation lines will be formed. The method includes using the singulation device to remove portions of the layer of material aligned to the singulation lines and thereafter plasma etching the semiconductor wafer from the first surface to the second surface through the spaces to form the singulation lines thereby singulating the semiconductor wafer.

In an example, a method of singulating semiconductor die from a semiconductor wafer includes providing the semiconductor wafer formed from a semiconductor material and having a plurality of semiconductor dies formed on a first surface of the semiconductor wafer, the plurality of semiconductor dies separated from each other by singulation regions where singulation lines are to be formed. The method includes providing a material on the second surface of the semiconductor wafer, the material having a thickness greater than about five (5) microns. The method includes attaching the semiconductor wafer to a first carrier substrate, wherein the material is interposed between the first carrier substrate and the semiconductor wafer. The method includes plasma etching a first opening to extend into the semiconductor wafer thereby creating first singulation lines between the plurality of semiconductor dies while the semiconductor wafer is attached to the first carrier substrate. The method includes forming second singulation lines extending from the first singulation lines through the material towards the first carrier substrate to singulate the material, wherein the second singulation lines comprise a narrower width than the first singulation lines. In a further example, the method can further include providing a protective structure over the first surface; and thinning the semiconductor wafer from the second surface to provide the semiconductor wafer with recessed portion and an outer edge, the outer edge being thicker than the recessed portion, wherein providing the material comprises forming the material over the recessed portion and the outer edge. In a still further example, the method can include removing the outer edge of the semiconductor wafer before the plasma etching step.

Other examples are included in the present disclosure. Such examples may be found in the figures, in the claims, or in the description of the present disclosure.

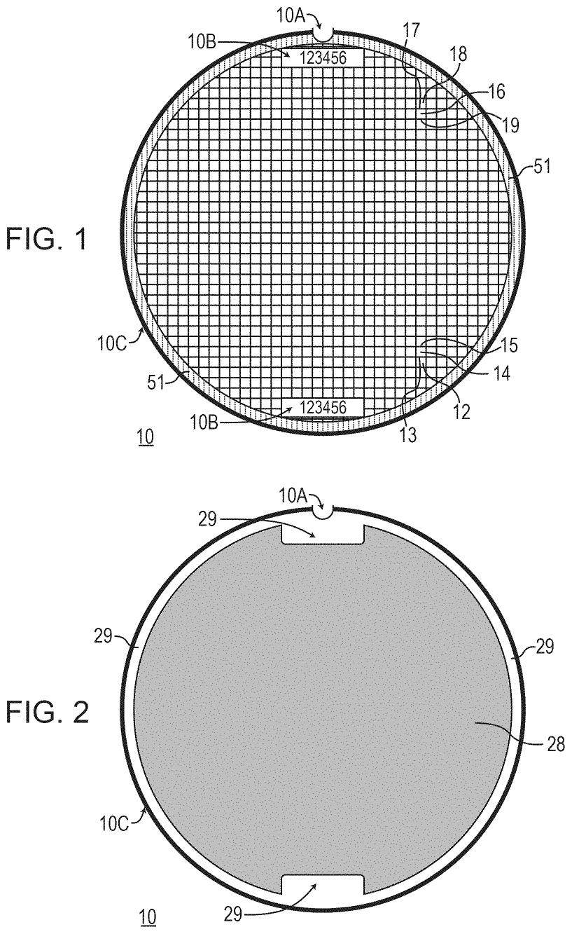

FIG. 1 is a reduced plan view that graphically illustrates a semiconductor substrate 10 at a later step in fabrication. More particularly, FIG. 1 illustrates the front side or active side of semiconductor substrate 10. In other examples, semiconductor substrate 10 can also be referred to a wafer or work piece. Semiconductor substrate 10 includes a plurality of semiconductor die, such as die 12, 14, 16, and 18, that are formed on or as part of semiconductor substrate 10. Die 12, 14, 16, and 18 are spaced apart from each other on semiconductor substrate 10 by spaces where singulation lines or singulation openings are to be formed or defined, such as scribe lines or singulation lines 13, 15, 17, and 19. More particularly, all of the semiconductor die on semiconductor substrate 10 generally are separated from each other on all sides by areas or spaces where scribe lines or singulation lines, such as singulation lines 13, 15, 17, and 19, are to be formed. Die 12, 14, 16, and 18 can be any kind of electronic device including semiconductor devices such as, diodes, transistors, discrete devices, integrated circuits, sensor devices, optical devices, or other devices known to one of ordinary skill in the art. In some examples, semiconductor substrate 10 can include a notch 10A formed through semiconductor substrate 10, and scribe data 10B used to identify semiconductor substrate 10 during the manufacturing process. It is understood that in other examples, the area used for scribe data 10B can instead be used for alignment structures 51 or together with alignment structures 51, In one example, semiconductor substrate 10 has completed wafer processing including the formation of a backside layer described later.

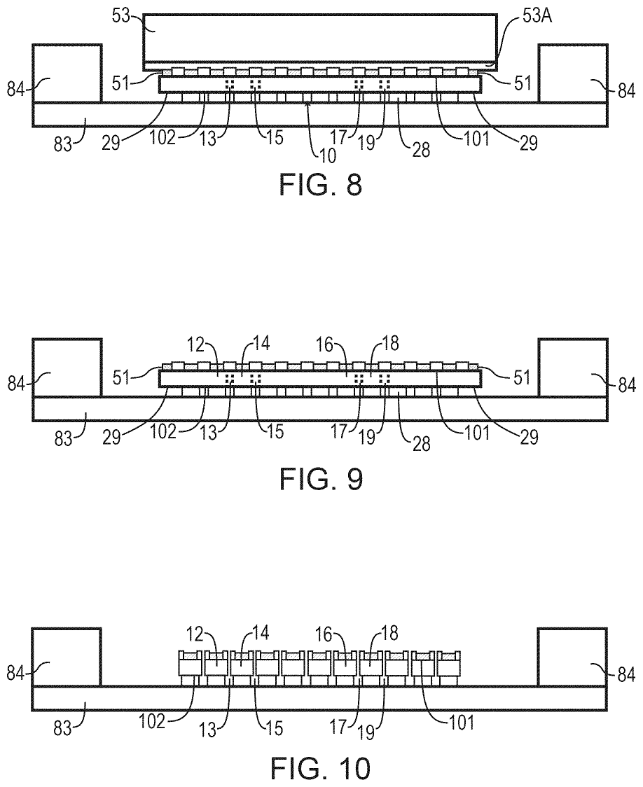

In accordance with the present description, semiconductor substrate 10 further includes alignment structures 51, which in the present example are provided around a peripheral edge region 10C of semiconductor structure 10. Specifically, peripheral edge region 10C is a region of semiconductor substrate 10 where semiconductor die, such as semiconductor die 12, 14, 16, 18, are not included so as to provide space for alignment structures 51. FIGS. 4A, 4B, and 4C illustrate examples of types of alignment structures 51 that can be used in accordance with the present description. FIG. 4A illustrates a plurality of parallel bars or stripes 51A; FIG. 4B illustrates a cross-pattern 51B; and FIG. 4C illustrates a “7” cross-pattern 51C. The “7” cross-pattern 51C can be useful for detecting the location of notch 10A on semiconductor substrate 10. That is, the “7” cross-pattern 51C can assist in providing the orientation of semiconductor substrate 10. These (or other) alignment structures can be provided around all or portion of peripheral edge region 10C of the front side of semiconductor substrate 10. In other examples, alignment structures 51 can be placed in other non-periphery areas on the front side of semiconductor substrate 10 where active devices are not formed. In some examples, alignment structures 51 can be placed on opposing sides or edges of semiconductor substrate 10. In some examples, alignment marks 51 can be further placed on partial dies or incomplete dies around the edge of semiconductor substrate 10.

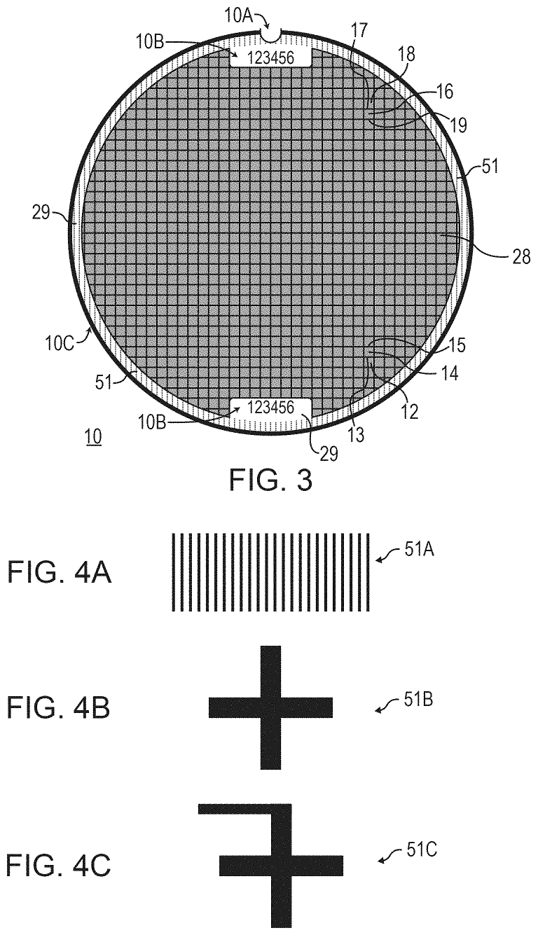

FIG. 2 illustrates a bottom view semiconductor substrate 10 including a material 28 formed on or over the back side of semiconductor substrate 10. Material 28 is a continuous layer that extends across the back side of semiconductor substrate that is configured to become part of semiconductor die 12, 14, 16, 18 when they are separated from semiconductor substrate 10 in subsequent processing. In some examples, material 28 can be a back metal structure, a wafer back coating (WBC) structure, a die attach film (DAF), or other structures known to one of ordinary skill in the art. In some examples, material 28 can be formed using evaporation, sputtering, plating, chemical vapor deposition, spin-on, laminating, printing, or other processing techniques as known to one of ordinary skill in the art. In some examples, material 28 can comprise a layer comprising aluminum (Al), a layer comprising copper (Cu), a layer comprising gold (Au), a layer comprising tin (Sn), a layer comprising gold-tin (AuSn), a layer comprising titanium (Ti), a layer comprising nickel (Ni), and a layer comprising silver (Ag). In other examples, material 28 can be a single layer of material.

In accordance with the present description, the material 28 is not deposited in or is removed from certain areas on the back side of semiconductor substrate 10, which correspond to the location of alignment structures 51 provided on the front side of semiconductor substrate 10. In the example illustrated in FIG. 2, material 28 is not deposited around peripheral edge region 10C of semiconductor substrate 10. In some examples, material 28 is not deposited on the back side of semiconductor substrate 10 that correspond to the location of scribe data 10B on the front side of semiconductor substrate 10 when, for example, alignment structures 51 are used instead of or in conjunction with scribe data 10B. Those portions of the back side of semiconductor substrate 10 where material 28 is not present can be referred to as masked-out areas or portions 29. In some examples, one or more masking layers, materials, or structures can be placed on or over the back side of semiconductor substrate 10 prior the deposition or formation of material 28 on back side surface. In some examples, a shadow mask or ring can be used to prevent the deposition of material 28 around the peripheral edge of the back side of the semiconductor substrate 10. In some examples, tabs or extensions can be added to the shadow mask to provide the masked-out areas where desired and with desired shapes. In other examples, tape materials, such as Kapton tape, can be used to mask-off desired locations on the back side of semiconductor substrate 10. Any material that can provide temporary masking that does not contaminate or interfere with the deposition process used to provide the material 28 can be used. That is, the masking material is selected to provide appropriate masking capability and to be compatible with the selected deposition process for providing material 28.

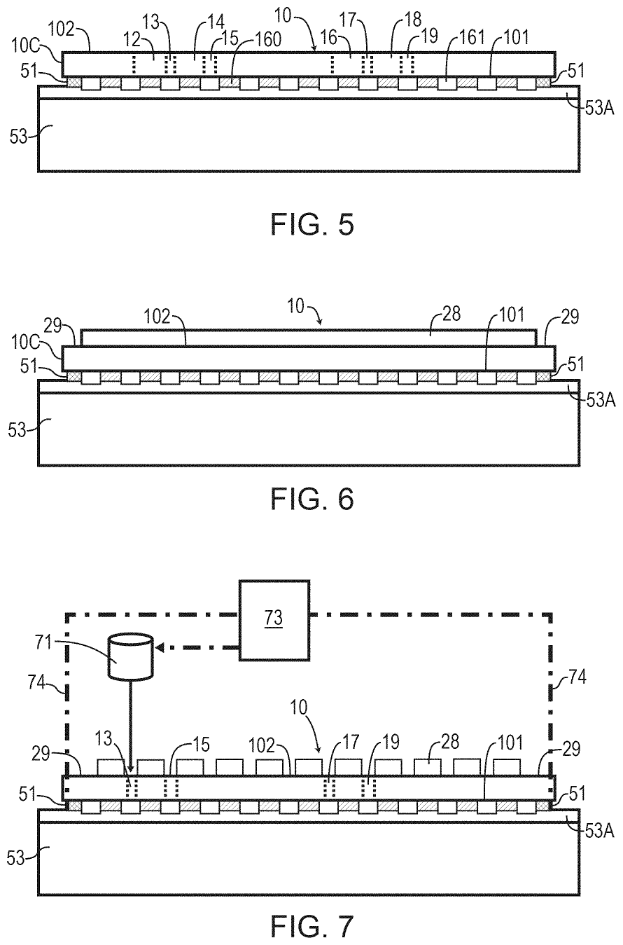

FIG. 3 illustrates a top view of semiconductor substrate 10 in a see-through configuration that shows both the active side with the individual die 12, 14, 16, and 18, the alignment marks 51, and material 28 on the back side of semiconductor substrate 10 with masked-out portions 29. In other applications, material 28 can be selectively removed from the area over and surrounding the alignment structures 51 using techniques such as laser ablation or patterning and etching. In accordance with the present description, masked-out portions 29 enable the use of infra-red (IR) alignment for singulating material 28 using, for example, laser singulation, laser ablation, or saw singulation of material 28 on the back side of semiconductor substrate 10 from the back side. This is illustrated, for example, in FIG. 7, which will be described in more detail later. Since IR cannot be used through material 28 to utilize alignment marks 51 on the front side of semiconductor substrate 10, the present description provides selected areas (that is, masked-out portions 29) without material 28 so that the IR signal can detect alignment marks 51 on the front side so as to ensure that material 28 is separated in correct alignment with the scribe lines 13, 15, 17, and 19 between semiconductor die 12, 14, 16, and 18 on the front side. This approach avoids the problems associated with complex optical alignment systems used previously. In addition, although IR cannot typically pass through a heavily doped substrate, it was unexpectedly found that if semiconductor substrate 10 is thin enough, the IR signal can effectively pass through the heavily doped starting wafer portion of semiconductor substrate 10 to support processing of power semiconductor devices. In some examples, an IR microscope can be used to provide the alignment capabilities of the present description.

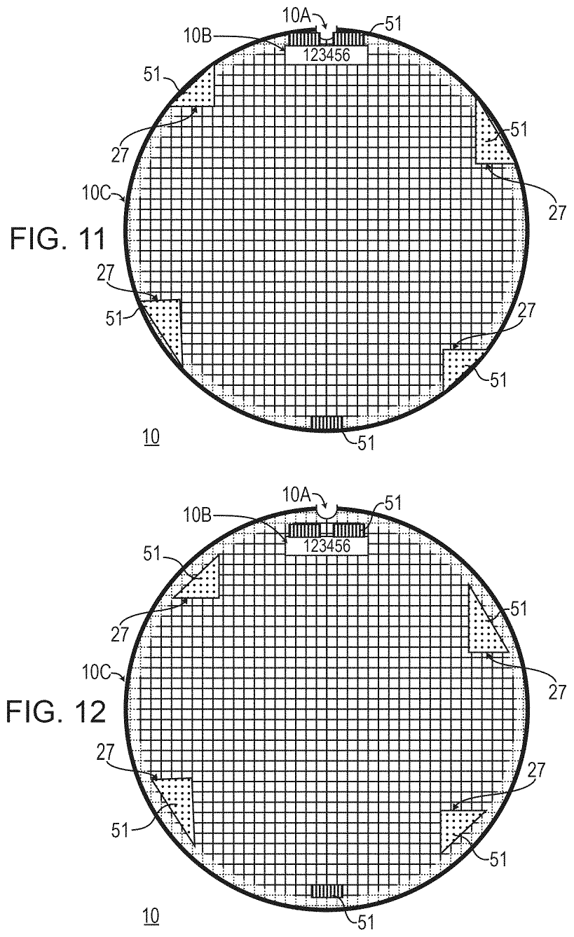

FIG. 5 illustrates a simplified side view of semiconductor substrate 10 in accordance with the present description. In the present example, semiconductor substrate 10 has finished front-end processing and is ready for back-end processing in accordance with the present description. In some examples, semiconductor substrate 10 is attached with an active side or front side 101 down and facing a wafer carrier or carrier substrate 53. As set forth previously, semiconductor substrates comprises a plurality of individual semiconductor devices or die (for example, 12, 14, 16, 18) separated from each other by singulation lines, scribe lines, or a scribe grid (for example, 13, 15, 17, 19). Such individual semiconductor devices can be integrated circuits, power discrete devices, sensor devices, optical devices, combinations thereof, or other electronic devices as known to one of ordinary skill in the art. In some examples, power semiconductor devices are used, and semiconductor substrate 10 comprises a heavily doped starting substrate and a more lightly doped semiconductor layer formed on or over the heavily doped starting substrate. In some examples, the starting substrate has a doping concentration greater than about 1.0×10¹⁹ atoms/cm³. Semiconductor substrate 10 can comprise silicon, other Group IV materials, combinations of Group IV materials, III-V materials, combinations thereof, or other materials as known to one or ordinary skill in the art. In some examples, the semiconductor substrate 10 can comprise a silicon-on-insulator (SOI) structure. Although not illustrated, the active side 101 of semiconductor substrate 10 can include doped layers and regions comprising N-type conductivity and P-type conductivity. In addition, metal interconnects layers 160 and dielectric layers 161 can be provided overlying active side 101 of semiconductor substrate 10. FIG. 5 further illustrates alignment structures 51 disposed at peripheral edge portion 10C of semiconductor substrate 10. In some examples, alignment structures 51 can be formed in metal interconnect layers 160 or dielectric layers 161. In other examples, alignment structures 51 can be etched or formed within semiconductor substrate 10.

As illustrated in FIG. 5, semiconductor substrate 10 is attached to carrier substrate 53, which may comprise, for example, a glass substrate or other substrates as known to one of ordinary skill in the art. In some examples, semiconductor substrate 10 can be attached to the carrier substrate with an adhesive material 53A, which may be included as part of carrier substrate 53. In some examples, adhesive material 53A can comprise a liquid ultra-violet (UV) curable adhesive. In other examples, a light-to-heat decomposable layer (not shown) can be interposed between carrier substrate 53 and adhesive material 53A to assist in the removal of carrier substrate 53 later in the fabrication process. Example carrier substrate systems are available from The 3M Company of Maplewood, Minn., U.S.A. In some examples, a protective structure or film (not illustrated) can be placed overlying active side 101 of semiconductor substrate 10 prior to attaching it to carrier substrate 53.

In some examples, after semiconductor substrate 10 is attached to carrier substrate 53, a portion of the total thickness of semiconductor substrate 10 is removed from back side 102 to provide a desired thickness for semiconductor substrate 10. At this point, the processed back side 102 can be referred to as a thinned surface. In some examples, the desired thickness is less than approximate 100 microns. In some examples, the desired thickness is approximately 10 microns to about 90 microns. In some examples, semiconductor substrate 10 has a diameter greater than or equal to 200 millimeters, but it is understood that present description is appropriate for smaller diameter semiconductor wafers as well. Removal techniques such as, grinding, polishing, etching, combinations thereof, or other removal techniques as known to one of ordinary skill in the art can be used to provide the thinned surface.

FIG. 6 illustrates a side view of semiconductor substrate 10 after additional processing. In some examples, material 28 is disposed overlying back side 102 of semiconductor substrate 10 except for masked-out portions 29. As stated previously, a shadow mask or ring can be used to prevent the deposition of material 28 around the peripheral edge of back side 102 of semiconductor substrate 10. In some examples, tabs or extensions can be added to the shadow mask to provide masked-out areas 29, which are in vertical alignment with alignment marks 51 as generally illustrated in FIG. 6. In other examples, tape materials, such as Kapton tape, can be used to mask-off desired locations on back side 102 of semiconductor substrate 10. In some examples, material 28 comprises a conductive material, such as one or more layers of metal. In some examples, material 28 comprises a layer comprising aluminum (Al), a layer comprising copper (Cu), a layer comprising gold (Au), a layer comprising tin (Sn), a layer comprising gold-tin (AuSn), a layer comprising titanium (Ti), a layer comprising nickel (Ni), and a layer comprising silver (Ag). Material 28 can be provided using evaporation, sputtering, plating, spin-on, printing, combinations thereof, or other techniques as known to one of ordinary skill in the art. In other examples, material 28 comprises a wafer back coating or a die attach film.

With reference to FIG. 7, semiconductor substrate 10 is illustrated during a back side singulation step where portions of material 28 are fully removed or thinned using a singulation apparatus 71. In some examples, the singulation step can include laser singulation, laser ablation, or saw singulation. In accordance with the present description, singulation apparatus 71 is aligned to singulate material 28 with alignment marks 51 using an alignment apparatus 73. In some examples, alignment apparatus 73 is an infrared (IR) alignment apparatus that provides an IR signal 74 through semiconductor substrate 10 from the masked-out portions 28 on back side 102 to the front side 101, and uses alignment marks 51 to remove portions of material 28 in alignment with singulation lines 13, 15, 17, and 19.

It was found that IR cannot be used through material 28 to utilize alignment marks 51 on the front side of semiconductor substrate 10, and thus, the present description provides selected areas (that is, masked-out portions 29) without material 28 so that the IR signal can detect alignment marks 51 on the front side so as to ensure that material 28 is separated in correct alignment with the scribe lines 13, 15, 17, and 19 between semiconductor die 12, 14, 16, and 18 on the front side. This approach avoids the problems associated with complex front to back optical alignment systems used previously, which required expensive equipment and required either thin wafer handling or optically clear wafer support structures such as optically clear rigid wafer carriers to be used. In addition, although IR cannot typically pass through a heavily doped substrate, it was unexpectedly found that if semiconductor substrate 10 is thin enough, the IR signal can effectively pass through the heavily doped starting wafer portion (for example, a doping concentration greater than 1.0×10¹⁹ atoms/cm³ proximate to back side 102) of semiconductor substrate 10 to support processing of power semiconductor devices. In some examples, an IR microscope can be used to provide the alignment capabilities of the present description.

FIG. 8 illustrates a side view semiconductor substrate 10 attached to another carrier substrate 83. In the present example, back side 102 of semiconductor substrate 10 with the singulated material 28 is placed adjacent to a major surface of carrier substrate 83. In some examples, carrier substrate 83 comprises a carrier tape or carrier film attached to frame structure 84. Frame structure typically comprises a rigid material that helps provides stability for semiconductor substrate 10 and carrier substrate 83 during subsequent processing.

FIG. 9 illustrates a side view of semiconductor substrate 10 after further processing. In some examples, carrier substrate 53 is removed exposing front side 101 of semiconductor substrate 10. In some examples, a laser can be used to change the composition of the light-to-heat decomposable layer thereby releasing carrier substrate 53. Adhesive material 53A can then be removed using, for example, a specialty tape. In some examples, front side 101 of semiconductor substrate 10 can include a patterned layer that has openings (not shown) corresponding to the singulation lines (for example, singulation lines 13, 15, 17, and 19) between semiconductor die (for example, semiconductor dies 12, 14, 16, and 18). In some examples, the patterned layer can be a dielectric material, such as silicon oxide, silicon nitride, or polyimide. In other examples, the pattern layer can be patterned photoresist.

FIG. 10 illustrates a side view of semiconductor substrate 10 after further processing. In some examples, a plasma singulation, etching, separating, or dicing process is used to remove material within the singulation lines between adjacent semiconductor die to separate the semiconductor die into appropriate units from the front side of semiconductor substrate 10 to the back side. In some examples, semiconductor substrate 10 mounted to the carrier tape and frame is placed within an etch apparatus, such as a plasma etch apparatus. Such apparatus are available from Plasma-Therm, LLC of Saint Petersburg, Fla., U.S.A.

In one example, semiconductor substrate 10 can be etched through the openings to form or define singulation lines (for example, singulation lines 13, 15, 17, 19) from front side 101 of semiconductor substrate 10 to back side 102 semiconductor substrate 10. The etching process can be performed using a chemistry that selectively etches silicon (or other semiconductor materials) at a much higher rate than that of dielectrics and/or metals. In one example, semiconductor substrate 10 can be etched using a process commonly referred to as the Bosch process. In some examples, semiconductor substrate 10 can be etched using the Bosch process in a deep reactive ion etch system. In some examples, the width of singulation lines 13, 15, 17, 19 can be from about five microns to about twenty microns. Such a width is sufficient to ensure that the openings that form singulation lines can be formed completely through semiconductor substrate 10. In some examples, the singulation lines can be formed in about five to about thirty minutes using the Bosch process. At this point, semiconductor substrate 10 has been separated into individual devices each with a portion of material 28, which was singulated prior to semiconductor substrate 10. In some examples, the semiconductor die (for example, semiconductor die 12, 14, 16, 18) can be cleaned and then removed from carrier substrate 83 using a pick-and-place system to place the separated semiconductor dies into package structures or printed circuit boards.

As described previously other materials can be used for material 28 on the back side of semiconductor substrate 10, such as die attach materials (die attach films (DAF) or wafer back coat (WBC) materials. In some examples, the laser process does not need to completely remove material 28. That is, just enough of material 28 can be removed so that any remaining portion is removed during a tape stretch process and/or pick and place removal of singulation die.

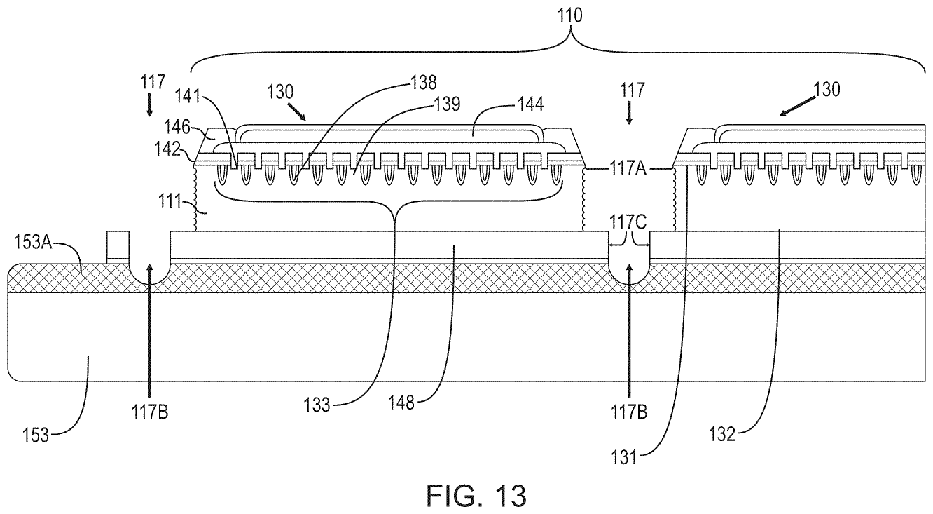

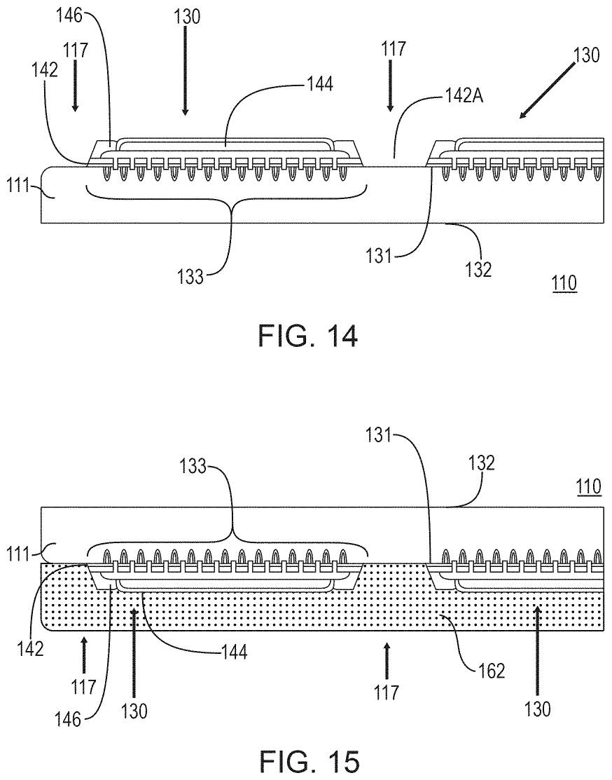

FIG. 11 illustrates a top view of another example of semiconductor substrate 10. In this example, the areas 27 for alignment keys 51 comprise other shapes, such as triangular shapes, placed in discrete areas around front side 101 of semiconductor substrate 10. FIG. 12 illustrates a top view of a further example, of semiconductor substrate 10. In this example, areas 27 for alignment keys 51 are placed inset of the peripheral edge region 10C of semiconductor substrate 10. Such a configuration can be useful for Taiko ring configured semiconductor wafers. In some examples, the inset can be in a range from about 1 mm to about 5 mm from the edge.

In summary, the method and structure provides alignment structures for aligning the back side of a processed semiconductor wafer for high volume production of laser back side metal ablation or other methods of material removal, such as sawing. The method and structure enables costs savings for 300 mm and larger processed semiconductor wafers having back metal layers. In addition, the method and structure increase throughput at laser ablation by reducing the thickness and diameter of the material needed to be removed and increasing the alignment tolerance. The present approach can be used in applications where alignment marks can be used to structure (e.g., remove portions of) back side materials using, for example, a laser or a saw process to open scribe lines for subsequent plasma singulation processes, particularly where photo-lithography is not a suitable option to provide scribe lines in the back side materials. In addition, the present approach can use alignment marks to structure (e.g., more portions of) coated polymer materials (which may not be photo sensitive to perform photo-lithography) with a laser process or a blade process to open scribe lines for plasma dicing where the coated polymer can be used as mask on the front side of the wafer. This coated polymer can be water soluble.

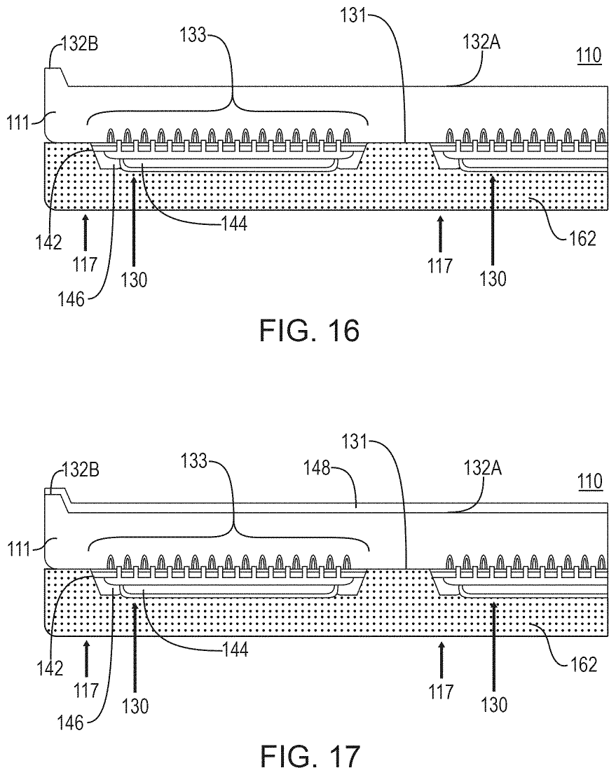

Turning now to FIGS. 13-22, methods for singulating substrates, such as semiconductor substrates, with thick back side material are described. It was found empirically that the singulation of semiconductor substrates with back side material is more difficult as the thickness of semiconductor substrates has decreased and/or the thickness of the back side material increases. Several issues have been encountered including, but not limited to, damage to the singulated semiconductor die when using saw singulation of such substrates. This damage has led to processing yield issues and device reliability issues. In addition, prior approaches to address these yield and reliability issues (as well as others) have required reduced sawing speeds and increased die inspection operations, which reduces manufacturing cycle time and adds cost. Other approaches have included a two-step sawing processing; however issues such as increased cycle time, die chipping, and metal stringers were encountered. Further, laser die singulation approaches have been found to have issues with material residues being deposited on singulated die sidewall surfaces, which have led to yield issues and reliability issues. Still further, back material photo-patterning has been unfeasible due to cost, warpage, and breakage particularly when the substrate is ultrathin. Adding carriers to the photo-patterning process increase manufacturing cost further reducing feasibility of the photo-patterning approach.

FIG. 13 illustrates a partial cross-sectional view of semiconductor devices 130 at a step in fabrication in accordance with the present description. In some examples, semiconductor devices 130 have completed front-end fabrication as a semiconductor substrate 110 or semiconductor wafer 110, and have been separated into individual devices. Each of semiconductor devices 130 includes an active surface 131 where semiconductor active structures 133 are provided. Active surface 131 also can be referred to as a major surface or front side of semiconductor devices 130. In the present example, semiconductor devices 130 are configured as vertical power metal-oxide-semiconductor field effect transistor (MOSFET) structure, and can include insulated trench gate structures 138, body regions 139, and source regions 141 disposed proximate to active surface 131. Insulating layers 142 can be disposed over active surface 131 to electrically insulate the various structures and regions, and can comprise oxides, nitrides, other insulating materials as known to one of ordinary skill in the art, or combinations thereof. A top side metal structure 144 can be disposed over active surface 131 and can be electrically coupled to body regions 139 and sources regions 141 through openings in insulating layers 142. In some examples, top side metal structure 144 can comprise a conductive plug structure having an adhesion layer, a seed layer, and a plug material. In some examples, top side metal structure 144 can further include other metals, such as aluminum, an aluminum alloy, or other materials as known to one of ordinary skill in the art. In some examples, top side metal structure 144 can further include a bump structure, such as a copper bump structure that can be capped with a layer of nickel and gold. Another top side metal structure (not shown) can be disposed elsewhere over active surface 131 to provide an electrical connection to insulated gate structures 138. In some examples a patterned passivation 146 can be provided adjoining side surfaces of top side metal structure 144. Patterned passivation 146 can comprise organic or inorganic materials. In some examples, patterned passivation 146 can comprise polyimide or similar materials as known to one of ordinary skill in the art.

Semiconductor devices 130 further include a back surface 132 opposite to active surface 131. In some examples, semiconductor devices 130 are formed as part of a substrate 111 having a heavily doped starting substrate with more lightly doped region disposed over the heavily doped substrate where active structures 133 are formed. In some examples, substrate 111 is configured as a thin or an ultrathin substrate, and can have a thickness in a range from about 20 microns to about 30 microns with 25 microns being a typical example. In the present power MOSFET example, the heavily doped starting substrate provides a drain region for semiconductor devices 130.

A back side material 148 is provided over, adjoining, or atop back surface 132, and, in the present example comprises a thick layer or layers of material. In some examples, thick can refer to a total thickness of about 5 microns or more. In other examples, thick can refer to a total thickness in a range from about 5 microns to 50 microns. In further examples, thick can refer to a total thickness in a range from about 5 microns to about 40 microns. In still further examples, thick can refer to a total thickness in a range from about 5 microns to about 30 microns. In other examples, thick can refer to a total thickness in a range from about 10 microns to about 30 microns or more.

Back side material 148 can also be referred to a material 148 or back side material structure 148. In some examples, material 148 comprises one or more conductive materials, such one or more metals. In some examples, material 148 comprises copper or other metal(s) as known to one of ordinary skill the art. In other examples, material 148 comprises a wafer back coating (WBC) or a die attach film (DAF). In some examples, material 148 is configured for attaching semiconductor devices 130 is a next level of assembly, such as package substrate, a printed circuit board, lead frame, or similar structures as known to one of ordinary skill in the art.

In accordance with the present description, a multi-step singulation method is used to singulate or separate semiconductor devices 130 from semiconductor wafer 110 into the individual devices. In some examples, semiconductor wafer 110 is attached to a carrier substrate 153, which may include an adhesive layer 153A. In some examples, carrier substrate 153 comprises a carrier tape, which may be further mounted to a frame, such as frame 84 described previously. In accordance with the present description, in a first step, a plasma etch singulation process, such as that described previously in conjunction with FIG. 10, is used to remove material from or etch substrate 111 to form an opening that creates singulation lines 117 through substrate 111 from active surface 131 extending through to back side surface 132. In some examples, the plasma etch step removes all of substrate 111 in singulation lines 117. In this way, a portion of material 148 is exposed within singulation lines 117. In other examples, the plasma etch step can be terminated before reaching material 148 with the remaining portion removed in a subsequent step. In some examples, the plasma etch step can form singulation lines 117 having a width 117A in a range from about 50 microns to about 70 microns with 60 microns being typical. In other examples, width 117A is in a range from about 35 microns to about 85 microns.

In a next step, a different singulation process other than the plasma etch process is used to singulate material 148 from the active side 131 of semiconductor devices 130 through singulation lines 177. In this way, material 148 is removed in a subsequent or second step starting where singulation lines 117 terminate proximate to a top side of material 148 and ending a bottom side of material 148 adjacent to carrier substrate 153. In some examples, a laser process or a sawing process is used to singulate material 48 within singulation lines 117 thereby providing an extension 117B of singulation lines 117 through material 48. Extension 117B can also be referred to as a second singulation line. In some examples, extension 117B has a width 117C that is different than width 117A. In some examples, width 117C is less than width 117A, and width 117C can be in a range of about 5 microns to about 30 microns with 10-20 microns being typical. In some examples, the sawing process can utilize a saw blade configured for copper and a reverse cut process can be used to minimize burring issues. In some examples, the saw blade can have width of about 10 microns.

In other examples, a protective coating (not shown) can be provided over active side 131. Such a protective coating can include water soluble protective coating, such as a HogoMax™ brand of water soluble coatings available from Disco Corporation of Tokyo, Japan.

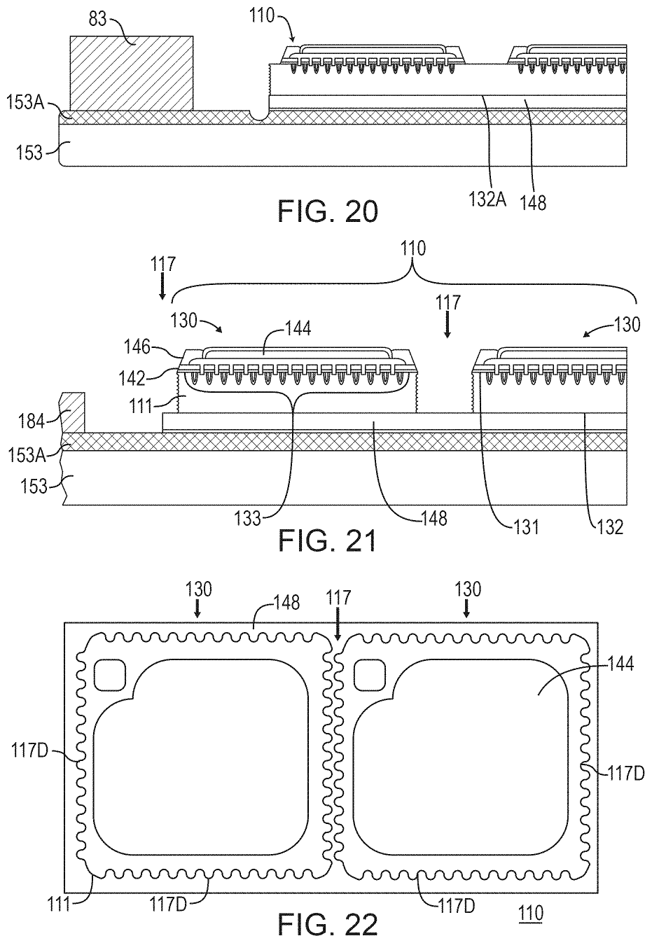

The multi-step singulation process described herein was found empirically to reliably singulate semiconductor devices, such as semiconductor device 130, while reducing or eliminating the issues described above with prior approaches. More particularly, the multi-step singulation process can enable improved die strength through improved die edge design (see for example, FIG. 22 described later), and the quality advantages of plasma etch singulation. Also, material 48 remains continuous after the first singulation step (that is, after the plasma singulation step) thereby providing support for thin semiconductor substrate applications up until the final singulation step. This provides both a cost and thin die handling advantage compared to patterned thick back side layer approaches. In addition, the multi-step singulation process described herein enables clean laser singulation without the contamination and die strength issues inherent with full laser singulation approaches. Further, by removing the semiconductor material separately by plasma etch singulation, more options for singulating material 48 or other back side support layers including, for examples, laser, saw, or other types of etching. Moreover, the multi-step singulation process enables more options to utilize other types of back side support layers that can be either conductive or non-conductive.

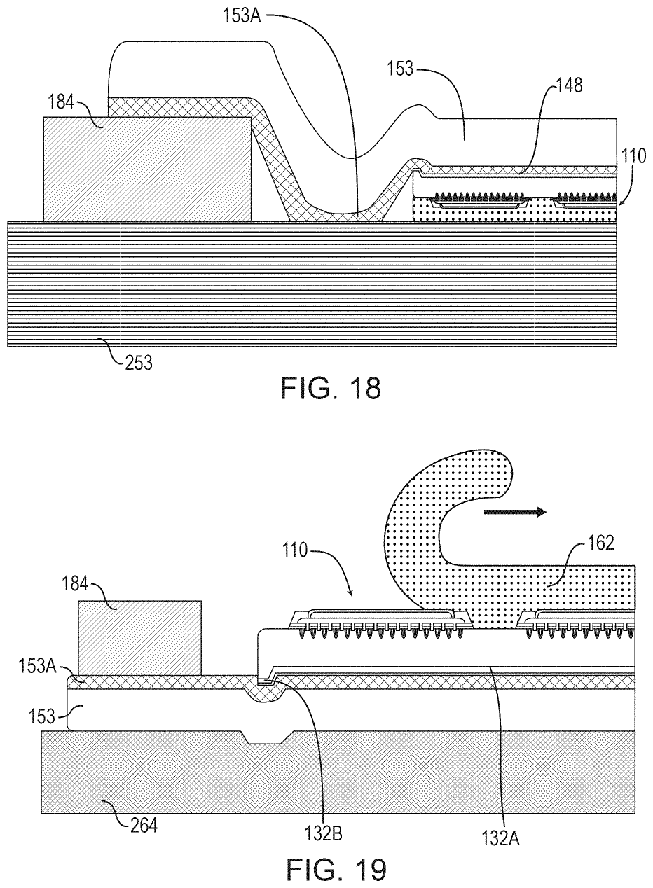

FIG. 14 illustrates a partial cross-sectional view of semiconductor wafer 110 with semiconductor devices 130 at a step in fabrication. In some examples, top side metal structures 144 have been provided over active side 131 and patterned passivation 146 has been provided adjacent to top side metal structures 144. In a next step, portions of insulating layers 142 are removed to provide openings 142A adjacent to active side 131 where singulation lines 117 will be formed. That is, the embodiment of FIG. 14 is an example of a plurality of die separated by singulation regions where singulation openings (e.g., singulation openings 117) are to be formed. In some examples, photo-masking and etching process can be used to provide patterned passivation 146 and openings 142A.

FIG. 15 illustrates a partial cross-sectional view of semiconductor wafer 110 after additional processing. In FIG. 15, semiconductor wafer 15 is illustrates as inverted or flipped to indicate that processing to back side 132 will be done in subsequent steps. In some examples, a protective structure 162 is provided over active side 131, which covers top side metal structures 144, patterned passivation 146, and openings 142A. In accordance with the present description, protective structure 162 is configured to protect active side 131 of semiconductor wafer 110 during subsequent processes. In some examples, protective structure 162 can comprise an adhesive type film, such as a back grinding tape, high temperature and chemically resistance liquid crystal polymer type back grinding adhesives, a UV-type back grinding tape, or similar films or structures as known to one of ordinary skill in the art. After protective structure 162 is applied or added, part of semiconductor wafer 110 from back surface 132 is removed to thin or reduce the thickness of semiconductor wafer to about 650 microns to about 700 microns with 675 microns being typical. Removal techniques, such as back grinding process techniques can be used. Part of semiconductor wafer 110 is removed at this step as well as a subsequent step described next to, among other things, reduce the series resistance of semiconductor wafer 110. This improves the performance of semiconductor devices 130.

FIG. 16 illustrates a partial cross-sectional view of semiconductor wafer 110 after further processing that is used to provide semiconductor wafer 110 as an ultrathin substrate or ultrathin wafer. More particularly, a center portion of semiconductor wafer 110 is further removed to provide a recessed portion 132A while leaving an outer edge 132B thicker than recessed portion 132A. In this way, outer edge 132B provides support for semiconductor wafer 110 during subsequent processing. That is, outer edge 132B reduces the likelihood that semiconductor wafer will break due to the ultrathin recessed portion 132A. In some examples, a Taiko grinding process can be used to provide recessed portion 131A and outer edge 132B. In some examples, after the Taiko etch semiconductor wafer 110 has a thickness of about 45 microns within recessed portion 132A. In some examples, a wet or dry etch can be used to further thin semiconductor wafer 110 in recessed portion 132A using, for example, near IR interferometry for endpoint detection. After the etch step, semiconductor wafer 10 can have a thickness of about 25 microns within recessed portion 132A.

FIG. 17 illustrates a partial cross-sectional view of semiconductor wafer 110 after additional processing. In some examples, material 148 is formed atop, along, or adjacent back surface 132 of semiconductor wafer 110 including recessed portion 132A and outer edge 132B. In some examples, material 148 comprises a multi-layer structure with a barrier layer, a seed layer, a thick layer, and a capping layer. In some examples, the barrier layer can comprise titanium, titanium nitride, or similar materials as known to one of ordinary skill in the art. In some examples, the seed layer can comprise copper, the thick layer can comprise copper, and the capping layer can comprise tin-silver. Material 148 can be formed using evaporation, sputtering, plating, spray-on, spin-on, roll-on, or other techniques as known to one of ordinary skill in the art. It is understood that different processes can be used for each of the layers that make up material 148. In some examples, the thick layer of copper has a thickness of about 10 microns. In accordance with the present description, protective structure 162 is configured to provide additional support for semiconductor wafer 110 during the steps for forming material 148 as well as for subsequent steps.

FIG. 18 illustrates a partial cross-sectional view of semiconductor wafer 110 after further processing. In some examples, semiconductor wafer 110 is attached to a vacuum work piece 253, such as a vacuum chuck. In some examples, semiconductor wafer 110 is attached to vacuum work piece 253 so that protective structure 162 is adjacent to vacuum work piece 253. In this way, protective structure 162 is interposed between semiconductor wafer 110 and vacuum work piece 253. Next, carrier substrate 153 (described previously) with adhesive layer 153A and attached to support frame 184 is placed over material 148. In some examples, a vacuum tape mount process can be used to attach carrier substrate 153 to semiconductor wafer 110, carrier substrate 253, and frame 184 as generally illustrated in FIG. 18. More particularly, the vacuum process enables carrier substrate 153 to better adhere to semiconductor wafer 110 and follow the profile of back side 132 (i.e., outer edge 132B and recessed portion 132A).

FIG. 19 illustrates a partial cross-sectional view of semiconductor wafer 110 after additional processing. In accordance with the present description, carrier substrate 153 is placed adjacent to a work surface 264, such as a vacuum chuck structure. Next, protective structure 162 is removed from semiconductor wafer 110. When protective structure 162 comprise a UV sensitive structure, the front side (that is active side 131) of semiconductor wafer 110 can be exposed to a UV light source enabling the removal of protective structure 162 from semiconductor wafer 110. In other examples, protective structure 162 can comprise a water soluble material allowing protective structure 162 to be dissolved or removed in water or another solvent. In some examples, semiconductor wafer 110 can then be cleaned and dried.

FIG. 20 illustrates a partial cross-sectional view of semiconductor wafer 110 after further processing. In some examples the outer perimeter of semiconductor wafer 110 including outer edge 132B is singulated away or separated away from semiconductor wafer 110 using, for example, a Taiko ring circle cut process. In some examples, a circle cut is formed between outer edge 132B and recessed portion 132A without damaging semiconductor devices 130. The circle cut singulates both semiconductor wafer 110 and material 148. Semiconductor wafer 110 then can be cleaned and dried. Next a portion of carrier substrate 153 adjacent to the singulated outer edge 132B can be locally exposed to a UV light source allowing removal of singulated outer edge 132B to provide the structure illustrated in FIG. 20.

FIG. 21 illustrates a partial cross-sectional view of semiconductor wafer 110 after additional processing. In accordance with the present description, semiconductor wafer 110 is exposed to the first step of the multi-step singulation processed described previously.

Specifically, plasma etch singulation is used to form singulation lines 117 to separate semiconductor wafer 110 into individual semiconductor devices 130. In a further step in the multi-step singulation process, material 48 is singulated using a sawing or laser singulation process as illustrated in FIG. 13 and described previously. In some examples, carrier substrate 153 conveniently provides support for semiconductor wafer 110 for the both singulation steps eliminating the need to place a different carrier substrate over active side 131 and removing carrier substrate 153 before singulating material 148. This beneficially reduces the chances for breakage or damage to semiconductor devices 130 as well as reduces cycle time.

FIG. 22 illustrates a partial top view of an example of semiconductor wafer 110 after singulation lines 117 are formed used plasma etch singulation, but before material 148 is singulated. In this example, side or edge surfaces of semiconductor devices adjacent to singulation lines 117 are plasma etched so as to have a rippled edge shape 117D in the top view of FIG. 22. That is, openings 142A (illustrated in FIG. 14) in insulating layers 142 can be formed to have the rippled edge shape, and the plasma etching process transfers or etches the rippled shape into substrate 111 along singulation lines 117. This is followed by the singulation of material 148 as described previously. The singulation of material 148 can either follow the rippled contours or can be linear and between the rippled contours. The rippled edge shape 117D was found to increase the die strength of semiconductor devices 130. Other die edge profiles, such as rounded die corners, triangles and other structure can be used to increase die edge strength.

From all of the foregoing, one of ordinary skill in the art can determine that in an example, a method for singulating a semiconductor wafer can comprise providing the semiconductor wafer having a plurality of semiconductor devices adjacent to a first surface; providing an alignment structure adjacent to the first surface; providing a material on a second surface of the semiconductor wafer, wherein the material is absent on the second surface directly below the alignment structure; removing portions of the layer of material using a laser, wherein the laser aligned to singulation lines on the first surface by passing an IR signal through the semiconductor wafer from the second surface to the first surface to detect the alignment structure; and plasma singulating the semiconductor wafer from the first surface to the second surface through the singulation lines.

In other examples, masking structures are used to prevent the formation of material at locations on back side of the semiconductor wafer correspondence to the location of the alignment structures on the front side. In some examples, the masking structures can be shadow masks that do not physically contact the back side. In other examples, the masking structures can be films or similar materials that are disposed onto the back side before the material is provided along the back side. In some examples, the masking structure comprises a tape. In other examples, the masking structure comprises a shadow ring comprise tab portions.

From all of the foregoing, one of ordinary skill in the art can determine that in an example, an apparatus for separating a layer of material on a semiconductor wafer can comprise a laser configured to remove portions of the layer of material; and an IR system configured to pass an IR signal through a back side of the semiconductor wafer to a front side of the semiconductor wafer to detect an alignment structure on the front side, the IR system further configured to align the laser so that the laser singulates the layer of material in alignment with singulation lines disposed on the front side of the wafer.

From all of the foregoing, one of ordinary skill in the art can determine that in an example, a method for singulating a semiconductor wafer can comprise providing the semiconductor wafer having a plurality of semiconductor devices adjacent to a first surface; providing an alignment structure adjacent to the first surface; providing a layer of material on a second surface of the semiconductor wafer, wherein the layer of material is absent on the second surface directly below the alignment structure; passing an IR signal through the semiconductor wafer from the second surface to the first surface to detect the alignment structure and align a saw to singulation lines on the first surface; using the saw to remove portions of the layer of material aligned to the singulation lines; and thereafter plasma etching the semiconductor wafer from the first surface to the second surface through the singulation lines. In another example, the method can further include attaching the second surface of the semiconductor wafer to a carrier substrate before plasma etching.

From all of the foregoing, one of ordinary skill in the art can determine that in an example, an apparatus for separating a material on a semiconductor wafer can comprise a removal apparatus configured to remove portions of the layer of material; and an IR system configured to pass an IR signal through a back side of the semiconductor wafer to a front side of the semiconductor wafer to detect an alignment structure on the front side, the IR system further configured to align the laser so that the laser singulates the layer of material in alignment with singulation lines disposed on the front side of the wafer. In another example, the apparatus can comprise a laser apparatus. In a further example, the removal apparatus can comprise a sawing apparatus. In a still further example, the removal apparatus can comprise both a laser apparatus and sawing apparatus.

In view of all of the above, it is evident that a novel structures and methods are disclosed. Included, among other features, is a multi-step approach to singulating a semiconductor wafer having an active side and a back side. A thick material structure is adjacent to the back side. In some examples, the semiconductor wafer is first singulated using plasma etch singulation to provide singulation lines that extend through the semiconductor wafer terminating proximate to the thick material structure. The thick material structure is then singulated using a different singulation process from the active side through the plasma etched semiconductor wafer. In some examples, the different singulation process comprises laser or saw singulation, which can form singulation lines in the thick material structure narrower than the singulation lines in the semiconductor wafer. The present approach separates the singulation process into multiple steps, enabling the advantages of different singulation techniques to be realized without the process limitations of each individually.

More particularly, the approach achieves the die strength, die edge design, and quality advantages from plasma dicing singulation. In addition, the continuous thick material structure can provide support for thin semiconductor wafer applications up until the final singulation step, providing both cost and thin die handling advantage compared to patterned thick backside layer approaches. Additionally, the approach enables clean laser singulation without the contamination and die strength issues inherent with full laser singulation. Further, by singulation the semiconductor wafer with plasma singulation separately to expose the thick material structure on the back side, reduced processing/tooling restrictions are enabled for separation of the thick material structure (saw, laser, etch or other); and multiple options are enabled for back side support layers both conductive and non-conductive.

In another approach, a method and structure has been described that provides alignment structures for aligning the back side of a processed semiconductor wafer for high volume production of laser back side metal ablation or other methods of material removal, such as sawing. The method and structure enables costs savings for 300 mm and larger processed semiconductor wafers having back metal layers. In addition, the method and structure increase throughput at laser ablation by reducing the thickness and diameter of the material needed to be removed and increasing the alignment tolerance.

While the subject matter of the invention is described with specific preferred examples, the foregoing drawings and descriptions thereof depict only typical examples of the subject matter, and are not therefore to be considered limiting of its scope. It is evident that many alternatives and variations will be apparent to those skilled in the art. For example, the back side material structures can comprise combinations of materials that may be deposited individually and annealed deposited as a plurality of layers and annealed as a composite structure. Various deposition techniques can be used for the back side material structures, including sputtering, plating, evaporation, printing, spin-on, lamination, roll-on, CVD, LPCVD, PECVD, MOCVD, ALD as well as other deposition techniques known to one of ordinary skill in the art. In addition, the back side laser does not need to be fully inside the final plasma singulated scribe grid opening, just close enough so that tape stretch and pick and place is not impacted.

As the claims hereinafter reflect, inventive aspects may lie in less than all features of a single foregoing disclosed example. Thus, the hereinafter expressed claims are hereby expressly incorporated into this Detailed Description of the Drawings, with each claim standing on its own as a separate example of the invention. Furthermore, while some examples described herein include some but not other features included in other examples, combinations of features of different examples are meant to be within the scope of the invention and meant to form different examples as would be understood by those skilled in the art.

What is claimed is:

1. A method of singulating semiconductor die from a semiconductor wafer comprising:
providing the semiconductor wafer formed from a semiconductor material and having semiconductor dies formed adjacent to a first surface of the semiconductor wafer, the semiconductor dies separated from each other by singulation regions where singulation lines are to be formed, wherein the first surface includes an alignment structure;
attaching the semiconductor wafer to a first carrier substrate, wherein the first surface of the semiconductor wafer is adjacent to the first carrier substrate;
removing a portion of the semiconductor wafer from the second surface to provide a thinned surface opposite to the first surface;
providing a material on the thinned surface of the semiconductor wafer except for an area corresponding to the location of the alignment structure on the first surface;
removing portions of the material using the alignment structure so that the removed portions of the material correspond to the singulation regions on the first surface; and
thereafter plasma singulating the semiconductor wafer through the singulation regions from the first surface inward towards the thinned surface.

2. The method of claim 1, wherein:
removing portions of the material comprises:
passing an infrared signal through the semiconductor wafer from the thinned surface to the front surface to detect the alignment structure on the first surface; and
laser ablating the material in accordance with the detected alignment structure.

3. The method of claim 1, wherein:
providing the material comprises:
masking part of the thinned surface that corresponds to where the alignment structure is on the first surface to provide a masked-out portion; and
forming the material over the thinned surface; and
the masked-out portion prevents the formation of the material at a location that corresponds to where the alignment structure is on the first surface.

4. The method of claim 3, wherein:
masking comprises using a masking material placed onto the thinned surface.

5. The method of claim 3, wherein:
masking comprises using a shadow mask.

6. The method of claim 1, wherein:
removing comprises laser ablating.

7. The method of claim 1, wherein:
providing the semiconductor wafer comprises providing a plurality of power semiconductor devices where the semiconductor wafer includes a starting substrate having a doping concentration greater than 1.0×10¹⁹ atoms/cm³.

8. The method of claim 1, wherein:
the alignment structure comprises a plurality of alignment structures;
a first portion of the plurality of alignment structure is disposed around a peripheral edge of the semiconductor wafer adjacent to the first side.

9. The method of claim 8, wherein:
a second portion of the plurality of alignment structures is provided in one or more non-peripheral regions.

10. The method of claim 1, wherein
the alignment structure comprises a shape configured to orient the semiconductor wafer.

11. A method for singulating a semiconductor wafer, comprising:
providing the semiconductor wafer having a plurality of semiconductor devices adjacent to a first surface, the plurality of semiconductor devices separated by spaces corresponding to where singulation lines will be formed;
providing an alignment structure adjacent to the first surface;
providing a material on a second surface of the semiconductor wafer, wherein the material is absent on the second surface directly below the alignment structure;
passing an IR signal through the semiconductor wafer from the second surface to the first surface where the material is absent to enable detection of the alignment structure and align a singulation device to the spaces where the singulation lines will be formed;
using the singulation device to remove portions of the material aligned to the singulation lines; and
thereafter plasma etching the semiconductor wafer from the first surface to the second surface through the spaces to form the singulation lines thereby singulating the semiconductor wafer.

12. The method of claim 11, further comprising:
attaching the second surface of the semiconductor wafer to a carrier substrate before plasma etching so that the material is interposed between the semiconductor wafer and the carrier substrate.

13. The method of claim 11, wherein:
using the singulation device comprises using a laser device; and
providing the semiconductor wafer comprises providing a thinned semiconductor wafer.

14. The method of claim 13, wherein:
the thinned semiconductor wafer has a thickness less than about 100 microns.

15. The method of claim 11, wherein:
using the singulation device comprises using a saw device; and
providing the material comprises:
providing a mask structure over a portion of the second surface;
forming a conductive layer on the second surface except where the mask structure is located; and
removing the mask structure.

16. A method of singulating semiconductor die from a semiconductor wafer comprising:
providing the semiconductor wafer formed from a semiconductor material and having a plurality of semiconductor dies formed on a first surface of the semiconductor wafer, the plurality of semiconductor dies separated from each other by singulation regions where singulation lines are to be formed;
providing a material on the second surface of the semiconductor wafer, the material having a thickness greater than about five (5) microns;
attaching the semiconductor wafer to a first carrier substrate, wherein the material is interposed between the first carrier substrate and the semiconductor wafer;
plasma etching a first opening to extend into the semiconductor wafer thereby creating first singulation lines between the plurality of semiconductor dies while the semiconductor wafer is attached to the first carrier substrate; and
forming second singulation lines extending from the first singulation lines through the material towards the first carrier substrate to singulate the material, wherein the second singulation lines comprise a narrower width than the first singulation lines.

17. The method of claim 16, wherein:
forming the second singulation lines comprises using a saw process.

18. The method of claim 16, wherein:
forming the second singulation lines comprises using a laser process.

19. The method of 16, further comprising:
providing a protective structure over the first surface; and
thinning the semiconductor wafer from the second surface to provide the semiconductor wafer with recessed portion and an outer edge, the outer edge being thicker than the recessed portion, wherein:
providing the material comprises forming the material over the recessed portion and the outer edge.

20. The method of claim 19, further comprising:
removing the outer edge of the semiconductor wafer before the plasma etching step.
